(19) United States
(12) Patent Application Publication
(10) Pub. No.: US 2015/0056820 A1
(43) Pub. Date: Feb. 26, 2015

(54) SYSTEMS AND METHODS OF SOLVENT TEMPERATURE CONTROL FOR WAFER COATING PROCESSES

(71) Applicant: GLOBALFOUNDRIES, Inc., Grand Cayman (KY)

(72) Inventors: Jason Lewis Behnke, Galway, NY (US); Christos Karanikas, Mechanicville, NY (US)

(73) Assignee: GLOBALFOUNDRIES, Inc., Grand Cayman (KY)

(21) Appl. No.: 13/971,312

(22) Filed: Aug. 20, 2013

(51) Int. Cl. H01L 21/67; H01L 21/02

(52) U.S. Cl. CPC H01L 21/67248; H01L 21/02282; H01L 21/6715
USPC 438/782; 118/712

(57) ABSTRACT

Systems and methods of solvent temperature control for wafer coating processes are provided. In an embodiment, a method for spin coating a wafer includes attaching the wafer to a rotatable chuck. The chuck is then rotated, and solvent is dispensed onto the wafer. The solvent dispensing temperature is controlled while the solvent is dispensed onto the wafer.

### TECHNICAL FIELD

The technical field relates to temperature control for solvents used in wafer coating processes, and more particularly relates to temperature control for solvents used in spin coating processes for wafers.

### BACKGROUND

The semiconductor industry is continuously moving toward the fabrication of smaller and more complex microelectronic components. Market pressures are expected to force manufactures to continue to reduce the size of microelectronic in the foreseeable future. The reduced size of microelectronic components has resulted in modified production processes handling smaller tolerances, with closer spacing of the various components. One result of the smaller, more closely spaced components is a reduced tolerance for mis-alignment in the manufacturing process.

Microelectronics are often produced on a silicon wafer. Some wafers will undergo hundreds or thousands of different manufacturing steps to produce a product. Spin coating is a common manufacturing technique that is utilized in the production of many microelectronic components. For example, lithographic methods spin coat photoresist compounds onto wafers to position particular features or components on the wafer. Anti-reflective coatings are also spin coated onto wafers in some production processes.

Spin coating is used to provide a layer of material with a relatively uniform thickness on the wafer, but the thickness of the spin coated layer is not completely uniform. As the size and spacing of microelectronic components shrink, variations in thickness of a spin coated layer become more significant. Smaller, more closely packed components require stricter tolerances, so a coating layer with a non-uniform thickness can result in unwanted residues or unwanted over-removal in thicker or thinner regions, respectively. Non-uniform thickness can have other undesired effects as well, such as shading of neighboring regions for angled manufacturing processes. Many manufacturing processes downstream from a spin coating process are calibrated to a specific coating layer thickness, so variations in thickness from one wafer to the next are also problematic.

Therefore, systems and methods of producing more uniform and more consistent coating layer thicknesses are desired. Many coating layers are applied at specified temperatures and spin rates, and the thickness of the coating varies as the manufacturing conditions change. A variety of solvents are used in the spin coating process, and variations in the solvent temperature introduce variations in the manufacturing conditions. These variations can result in inconsistent or non-uniform coating layer thicknesses.

Accordingly, it is desirable to provide a system for controlling the temperature of solvents during the spin coating process to improve the uniformity and consistency of the spin coated layer. In addition, it is desirable to develop a method for controlling the temperature of the solvents during the spin coating process. Furthermore, other desirable features and characteristics of the present invention will become apparent from the subsequent detailed description of the invention and the appended claims, taken in conjunction with the accompanying drawings and this background of the invention.

### BRIEF SUMMARY

A spin coating system is provided for coating a wafer. The system includes a rotatable chuck with an attachment point for attaching the wafer to the chuck. A solvent dispensing system is configured to dispense solvent on the wafer, and a solvent temperature sensing element is coupled to the solvent dispensing system. The spin coating system also has a heat transfer system coupled to the solvent temperature sensing element and to the solvent dispensing system, and the heat transfer system is configured to adjust the temperature of solvent in the solvent dispensing system.

In another embodiment, the spin coating system includes a rotatable chuck with an attachment point for attaching the wafer to the chuck. A solvent dispensing system has a nozzle positioned to dispense on the wafer. A heat transfer system includes a heat transfer device coupled to the solvent dispensing system, and a heat transfer temperature sensing element. The heat transfer system is configured to adjust the temperature of a heat transfer fluid in response to readings from the heat transfer temperature sensing element.

A method for spin coating the wafer includes attaching the wafer to the chuck. Solvent is dispensed onto the wafer, and the chuck is rotated. The solvent dispensing temperature is controlled while the solvent is dispensed onto the wafer.

### BRIEF DESCRIPTION OF THE DRAWINGS

The various embodiments will hereinafter be described in conjunction with the following drawing figures, wherein like numerals denote like elements, and wherein:

FIG. 1 is schematic drawing of a spin coating system in accordance with an exemplary embodiment with a wafer in position for receiving a coating material.

FIG. 2 is a side view of a wafer with a coating, where the coating is shown removed from one side of the wafer and present on the other side of the wafer;

FIG. 3 is a schematic drawing of a heat transfer system in accordance with an exemplary embodiment;

FIG. 4 is a side view of a heat exchanger in accordance with an exemplary embodiment;

FIG. 5 is a cutaway perspective view of a solvent line with a tracing line in accordance with an exemplary embodiment;

FIG. 6 is a schematic view of a solvent dispensing system in accordance with an exemplary embodiment;

FIG. 7 is a schematic view of a coating fluid dispensing system in accordance with an exemplary embodiment, and a wafer on a chuck;

FIG. 8 is a schematic view of a spin coating system with a heat transfer system coupled to a solvent dispensing system for dispensing reduced resist consumption solvent, in accordance with an exemplary embodiment;

FIG. 9 is a schematic view of a spin coating system with a heat transfer system coupled to a solvent dispensing system for dispensing back side rinse solvent, in accordance with an exemplary embodiment; and

FIG. 10 is a schematic view of a spin coating system with a heat transfer system coupled to a solvent dispensing system for dispensing edge bead removal solvent, in accordance with an exemplary embodiment.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

Coatings are routinely applied to wafers by spin coating during the microelectronics manufacturing process. The spin coating process often includes the application of various solvents to a wafer. The temperature of the wafer is equilibrated within relatively narrow tolerances before beginning the spin coating process, and relatively small changes in the wafer temperature can change the coating thickness and uniformity. It has been discovered that variations in the temperature of some solvents will change the thickness of the coating. Therefore, a temperature control system is added to the spin coating system to control the solvent temperature during application.

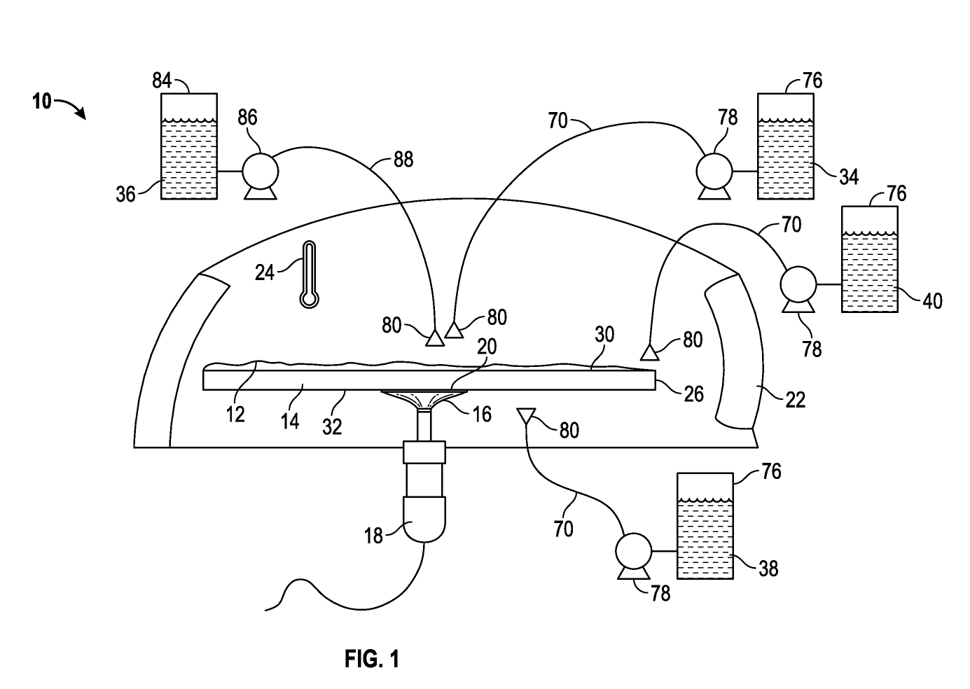

Referring now to FIG. 1, in accordance with an exemplary embodiment, a spin coating system 10 is used to apply various coatings 12 to a wafer 14. The wafer 14 is typically made of silicon, and may be essentially pure silicon, doped silicon, or another semiconductor, such as selenium (Se) or other semiconductor materials. The spin coating system 10 includes a chuck 16 that rotates about its axis to spin the wafer 14. A motor 18 is typically connected to the chuck 16 to provide the motive force, but other sources of motive force could also be used as long as the chuck 16 can be rotated. The chuck 16 includes an attachment point 20 for attaching the wafer 14 to the chuck 16. The chuck 16 and wafer 14 may be positioned within an enclosure 22 for the spin coating process. In many embodiments, operation of the spin coating system 10 is highly automated, so a robot or other mechanical device controls the various steps in the process.

The spin coating process will vary in different embodiments, and many of the steps described below are repeated or omitted in various embodiments. The process begins by connecting the wafer 14 to the chuck 16. In many embodiments, the attachment point 20 is a vacuum system, similar to a suction cup, that holds the wafer 14 in place. The attachment point 20 is generally designed such that there is no damage or permanent change to the wafer 14 from attachment to the chuck 16. The wafer 14 is thin in many embodiments, such as about 500 to about 1,000 microns, so care is needed to prevent breaking or damaging the wafer 14 during placement and attachment to the chuck 16.

After attachment to the chuck 16, the wafer 14 is brought to a controlled hold temperature 24. The hold temperature 24 varies for different coating materials, solvent loadings, spin rates, etc., but in one embodiment the hold temperature 24 is about room temperature. For example, a hold temperature 24 of about 20 degrees centigrade (° C.) is used in some embodiments, but hold temperatures of about 22° C., 25° C., 28° C., or other temperatures can also be used. In other embodiments, the hold temperature 24 is noticeably above or below room temperature. The wafer 14 is held on the chuck 16 for a hold time to allow the wafer 14 to equilibrate to the hold temperature 24, where the space inside the enclosure 22 is maintained at the hold temperature 24. The hold time may be about 1 second to about 2 minutes, but other hold times are also possible.

Once the wafer 14 has equilibrated to the hold temperature 24, various materials are applied to the wafer. The wafer 14 has a coating side 30 and a back side 32 opposite the coating side 30. In one embodiment, a solvent for reduced resist consumption solvent, also referred to as a reduced resist consumption solvent (RRC), 34 is applied near a center point of the wafer 14 on the coating side 30, such as within 1 centimeter (cm) of the center point. However, in other embodiments, the RRC 34 is applied to the coating side 30 at locations further removed from the center point. In this description, materials designated as “solvents” are materials that are not intended to remain on the wafer 14 to aid in further processing or manufacturing steps. Most of the applied solvents do not remain on the wafer 14 when the wafer 14 is removed from the spin coating system 10, but there may be a residue in some embodiments. The solvents may either spin or drip off the wafer 14 or evaporate, and no appreciable solvent residue is left behind for manufacturing processes downstream from the spin coating process.

In some embodiments, the RRC solvent 34 is applied prior to the coating fluid 36, where the coating fluid 36 contains a material that will remain on the wafer 14 after the wafer 14 leaves the spin coating system 10. In other embodiments, the RRC solvent 34 is applied while the coating fluid 36 is applied. The RRC solvent 34 aids the coating fluid 36 in spreading over the wafer 14, and results in a lower volume of coating fluid 36 to achieve a target thickness. Many coating fluids 36 are expensive, so the RRC solvent 34 saves on coating fluid costs. The RRC solvent 34 is applied either before the wafer 14 begins to spin, after the wafer 14 begins to spin, or the RRC solvent 34 application begins before the wafer 14 starts to spin and continues as the wafer 14 starts spinning. The total amount of RRC solvent 34 applied can be about 0.2 to about 2 milliliters (ml), but other quantities are also possible. Several different RRC solvents 34 are available, such as gamma butyrolactone, 1-methoxy-2-propanol aka propylene glycol monomethyl ether (PGME), 1-methoxy-2-propanol acetate (PGMEA), ethyl lactate, n-butyl acetate, and 4-methyl-2-pentanol.

Either after or during the RRC solvent 34 application, the coating fluid 36 is applied to the coating side 30 of the wafer 14. The coating fluid 36 is applied either before or after the wafer 14 begins spinning in various embodiments. In many embodiments, the RRC solvent 34 and the coating fluid 36 are dispensed onto the wafer 14 at close to the same point, and often within about 5 millimeters (mm) of each other. Centrifugal force from the spinning wafer 14 spreads the coating fluid 36 over the surface of the coating side 30 of the wafer 14. The coating fluid 34 typically includes a residual material that will remain on the wafer 14 as a coating 12, and a solvent that keeps the residual material in a liquid state for the spin coating process. The solvent in the coating fluid 34 is evaporated to leave a solid coating 12 on the wafer 14. In some photoresist embodiments, the residual material includes a resin, which serves to bind the coating 12, and an inhibitor or sensitizer that is the photoactive ingredient. Many other embodiments are also possible for the coating fluid 34. The wafer 14 may be moved to a different location to evaporate the solvent from the coating fluid 34, but the evaporation of the solvent is still considered part of the spin coating system 10. Moving the wafer 14 to another location to evaporate the solvent from the coating fluid 36 frees the chuck 16 for another wafer 14, which lowers the spin coating cycle time. There may be one or more applications of coating fluid 36, and the RRC solvent 34 can be applied or skipped between different coating fluid applications. In many embodiments, the coating 12 is between about 35 nanometers (nm) to several microns, but other thicknesses are also possible.

The coating fluid 36 tends to flow to the wafer outer edge 26, and sometimes flows onto the wafer back side 32. This leaves a residue on the wafer back side 32, and the residue can interfere with downstream manufacturing processes. A back side rinse (BSR) solvent 38 can be applied to the wafer back side 32 to remove the residue. The BSR solvent 38 is applied during or after the coating fluid 36 application, and if applied concurrently with the coating fluid 36 application the BSR solvent 38 application continues for a period of time after the coating fluid 36 application stops. The BSR solvent 38 dissolves and removes the residue from the wafer back side 32.

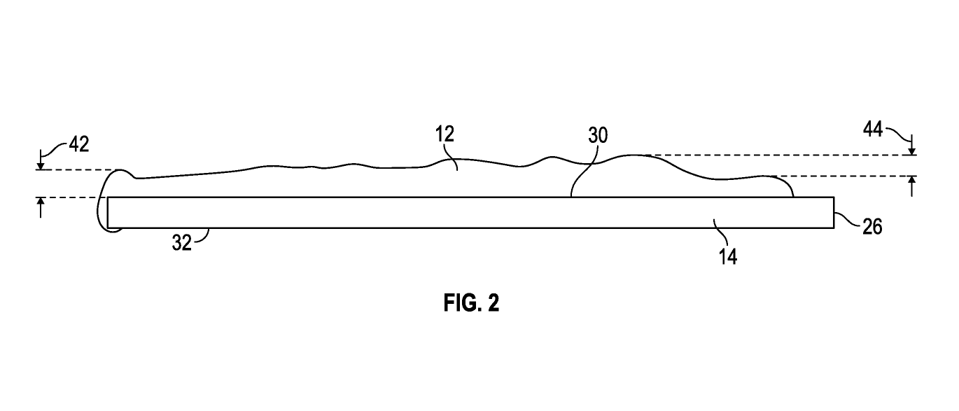

The coating fluid 36 also tends to leave a bead, or a slight rise, on the coating side 30 near the wafer outer edge 26, so the coating 12 tends to be slightly thicker there, as shown in FIG. 2, with continuing reference to FIG. 1. An edge bead removal (EBR) solvent 40 is applied to the coating side 30 of the wafer 14 approximately at the wafer outer edge 26 to remove the slight rise in the coating 12. In some embodiments, the EBR solvent 40 is applied within about 5 millimeters (mm) to about 0 mm of the wafer outer edge 26 on the coating side 30, but other distances are also possible.

During processing, the use of the BSR solvent 38 can change the thickness of the coating 12 on the coating side 30 of the wafer. Several tests were conducted measuring the coating thickness 42, indicated by arrows, at several different locations on the wafer coating side 30, so as to determine a coating thickness variation 44. Some of the tests were conducted when no BSR solvent 38 was used, and others were conducted when a BSR solvent 38 was used. The standard deviation in coating thickness 42 for coatings 12 applied without a BSR solvent 38 was about 0.12 nm, and the standard deviation in coating thickness 42 for coatings 12 applied with a BSR solvent 38 was about 0.25 nm, or about twice that of no BSR solvent 38. Coatings 12 when BSR solvent 38 was used also had an average thickness of almost 0.3 nm more than coatings 12 when no BSR solvent 38 was used. The BSR solvent 38 and the coating fluid 36 were dispensed on opposite sides of the wafer 14, so there was no direct contact of the BSR solvent 38 and the coating fluid 36 over the vast majority of the wafer 14. There may have been some minor interaction at the wafer outer edge 26, but the larger coating thickness variations 44 were present over the entire coating side 30 of the wafer 14.

In some tests, the BSR solvent 38 was added while the coating fluid 36 was applied, and in other tests the BSR solvent 38 was added only after the coating fluid 36 was applied. The test results were essentially the same when the BSR solvent 38 was added during the coating fluid 36 application and when the BSR solvent 38 was added after the coating fluid 36 application. Bulk BSR solvent 38 was not kept in a temperature controlled area, and the difference in the hold temperature 24 (which is the wafer temperature when the coating fluid 36 is applied) and the bulk BSR solvent 38 was only about 1° C. to about 2° C. Because the BSR solvent 38 does not directly interact with the coating fluid 36, it was determined the temperature change induced by the BSR solvent 38 impacted the coating thickness 42. The BSR solvent 38 negatively impacted the coating thickness variation 44 even when applied after the coating fluid 36, so it was theorized that the change in temperature impacted the coating fluid viscosity, thermal expansion, or some other property of the coating fluid 36 enough to change the coating thickness 42.

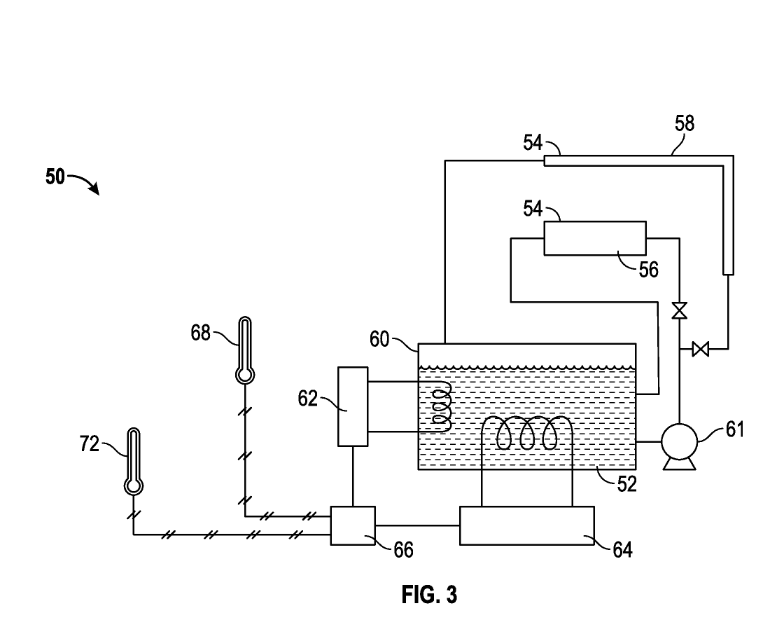

The coating 12 has a less consistent coating thickness 42 when the BSR solvent 38 is used, and there may be similar results for other solvents, such as the RRC solvent 34 and the EBR solvent 40. Therefore, to reduce the coating thickness variation 44, and to improve coating thickness 42 consistencies between different wafers 14, a heat transfer system 50 is used to control the temperature of the solvents applied during the spin coating process, where an exemplary embodiment is shown in FIG. 3 with continuing reference to FIGS. 1 and 2. The heat transfer system 50 is configured to adjust the temperature of the solvent in response to a reading from a temperature sensing element. Many solvents are relatively volatile, so they will evaporate when dispersed on a wafer 14. The evaporation of the solvent will result in evaporative cooling, so the proper solvent dispensing temperature may be different than the hold temperature 24 for the wafer 14. The best solvent dispensing temperature can be determined experimentally, and the best solvent dispensing temperature might vary from one solvent to another and from one coating fluid 36 to another. Therefore, different experimental testing for each solvent and coating fluid 36 can be used.

Several tests can be run to experimentally determine the solvent dispensing temperature for use in the spin coating system 10. Different experimental testing processes can be used, but one embodiment is described herein. The first step is to establish standard conditions for the coating process, including a hold temperature 24 and a rotation speed for the wafer 14. Next, several wafers 14 are coated at the standard conditions, except the solvent dispensing temperature of a selected solvent is varied and recorded. The coating 12 is cured, and the coating thickness 42 is measured at several points on each wafer 14. The coating thicknesses 42 are measured at the same general locations on each wafer 14. The coating thickness variation 44 and total coating thickness 42 is determined based on the measurements, and an acceptable range is determined for the solvent dispensing temperature. The desired solvent dispensing temperature can be based on a variety of factors, such as (a) most consistent coating thickness on a single wafer 14, (b) most consisting coating thickness for different wafers 14, (c) a measured coating thickness closest to a desired coating thickness, or (d) other factors. The testing provides a desired solvent dispensing temperature, or a set point for the temperature, as well as an acceptable range for the solvent dispensing temperature. For example, the most consistent coating thickness 42 may be a BSR solvent dispensing temperature of about 24° C., but solvent dispensing temperatures ranging from about 23° C. to about 25° C. may give acceptably consistent coating thicknesses 42. Once a desired solvent dispensing temperature is determined for one solvent, that solvent dispensing temperature is set as a standard condition and the process is repeated for the next solvent.

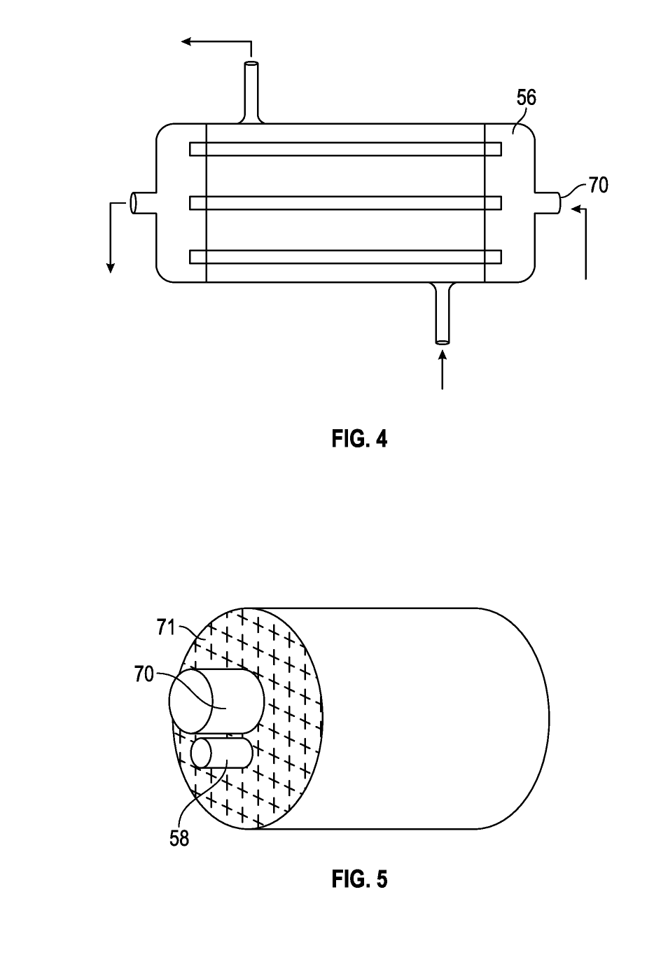

Once the solvent dispensing temperature is determined, a heat transfer system 50 is used to control the solvent dispensing temperature to within an acceptable range. The heat transfer system 50 has several components. A heat transfer device 54 is a device that transfers heat from a heat transfer fluid 52 to the solvent. The heat transfer device 54 may be a heat exchanger 56, a tracing line 58, a radiant heat transfer system, or other devices, as shown in FIGS. 4 and 5, with continuing reference to FIGS. 1-3. In some embodiments, the heat transfer device 54 is coupled to a solvent line 70 for heat transfer. In many embodiments, insulation 71 is positioned about the solvent line 70 to minimize unwanted changes in solvent temperature. In other embodiments, the heat transfer device 54 is coupled to other components of the solvent dispensing system, as long as the solvent dispensing temperature can be controlled within an acceptable solvent dispensing temperature range. The heat transfer fluid 52 can be a gas, but in many embodiments it is a liquid such as water or a glycol and water mixture. In many embodiments the heat transfer system 50 also includes a heat transfer fluid tank 60 for storing bulk heat transfer fluid 52, and a heat transfer pump 61 moves heat transfer fluid 52 from the heat transfer fluid tank 60 through the heat transfer device 54 and back to the heat transfer fluid tank 60. A cooling element 62 and/or a heating element 64 are used to increase or decrease the temperature of the heat transfer fluid 52, and the cooling and/or heating elements 62, 64 can be positioned in the heat transfer tank 60 or in other locations. In other embodiments, two streams of different temperature are mixed together to produce a heat transfer fluid 52 with the desired temperature, and the heat transfer fluid 52 is discarded after use. Many other embodiments are also possible.

In the heat transfer system embodiment shown in FIG. 3, a heat transfer control unit 66 is coupled to a heat transfer temperature sensing element 68 and a solvent temperature sensing element 72. The heat transfer temperature sensing element 68 is positioned to measure the temperature of the heat transfer fluid 52, and the solvent temperature sensing element 72 is positioned to measure the temperature of the solvent. The temperature sensing elements 68, 72 can be thermocouples, thermometers, radiant heat sensing devices, or other devices capable of measuring temperature. In some embodiments, the solvent temperature sensing element 72 is positioned to measure the solvent temperature close to the point of application onto the wafer 14, such as within about 1 to about 4 centimeters (cm) of a dispensing nozzle. The heat transfer control unit 66 is coupled to the cooling element 62 and/or the heating element 64, and adjusts the amount of cooling/heating based on the temperature of one or both of the heat transfer temperature sensing element 68 or the solvent temperature sensing element 72.

The heat transfer system 50 can be oversized for the amount of solvent dispensed, so much so that controlling the temperature of the heat transfer fluid 52 effectively controls the solvent dispensing temperature. For example, in some embodiments less than 3 ml of solvent are dispensed on a wafer 14. Therefore, a heat transfer system 50 that transfers heat from 1,000 ml of heat transfer fluid 52 to 3 ml of solvent would bring the solvent to the temperature of the heat transfer fluid 52. If the heat transfer system 50 is sized and configured to flow very large quantities of heat transfer fluid 52 past the solvent line 70, the heat transfer system 50 can control the temperature of the solvent by reading the heat transfer temperature sensing element 68. In this embodiment, there is no need for a solvent temperature sensing element 72 because the solvent is brought to the temperature of the heat transfer fluid 52.

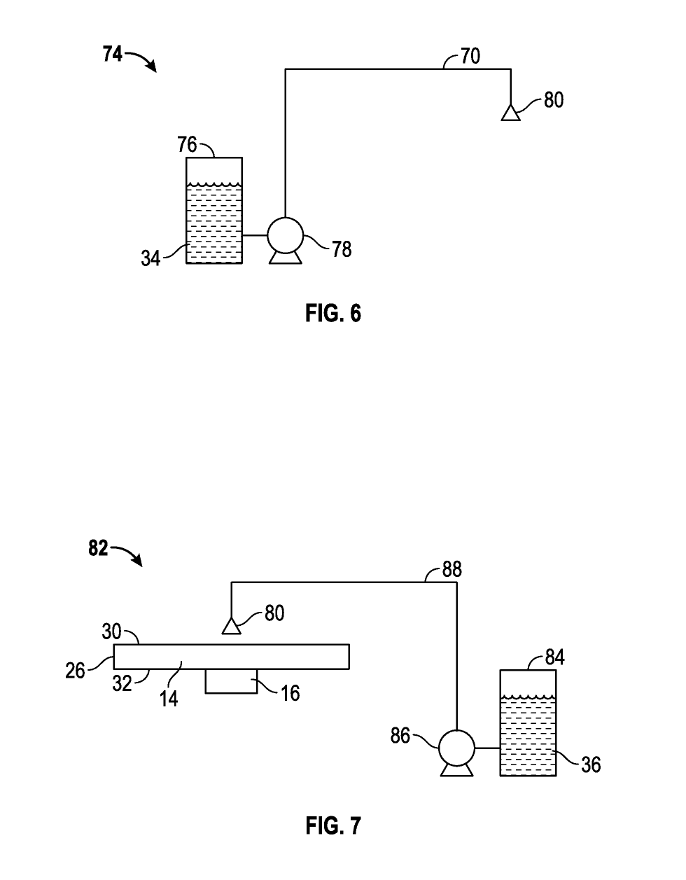

In an exemplary embodiment, solvent is dispensed from a solvent dispensing system 74, as illustrated in FIG. 6 with continuing reference to FIGS. 1-5. In some embodiments, the solvent dispensing system 74 includes a solvent line 70, a solvent storage tank 76, a solvent pump 78, and a nozzle 80. In other embodiments, the solvent tank 76 can be pressurized so no solvent pump 78 is needed, and other embodiments are also possible. The solvent storage tank 76 can be as simple as a drum, bucket, or tote bin, but in other embodiments the solvent storage tank 76 is a dedicated tank. A wide variety of pumps can be used for the solvent pump 78, but the solvent pump 78 should be able to dispense small quantities of solvent, such as 0.1 to 20 ml at a time. In many embodiments, the total solvent discharged per wafer is less than 30 ml. A wide variety of effective nozzles 80 are available, and essentially any hole that allows solvent to escape the solvent line 70 can be used, but some nozzle designs are more effective than others.

The coating fluid 36 is dispensed from a coating fluid dispensing system 82, in an exemplary embodiment, as shown in FIG. 7 with continuing reference to FIGS. 1-6. The coating fluid dispensing system 82 includes a coating fluid tank 84, a coating fluid pump 86, a coating fluid line 88, and a nozzle 80. In an exemplary embodiment, the nozzle 80 is positioned to dispense near the center point of the coating side 30 of a wafer 14 positioned on the chuck 16, and the coating fluid nozzle 80 is positioned within 5 mm of the reduced resist consumption solvent line nozzle 80. However, other embodiments are also possible. As with the solvent dispensing system 74, several variations and different embodiments can be used.

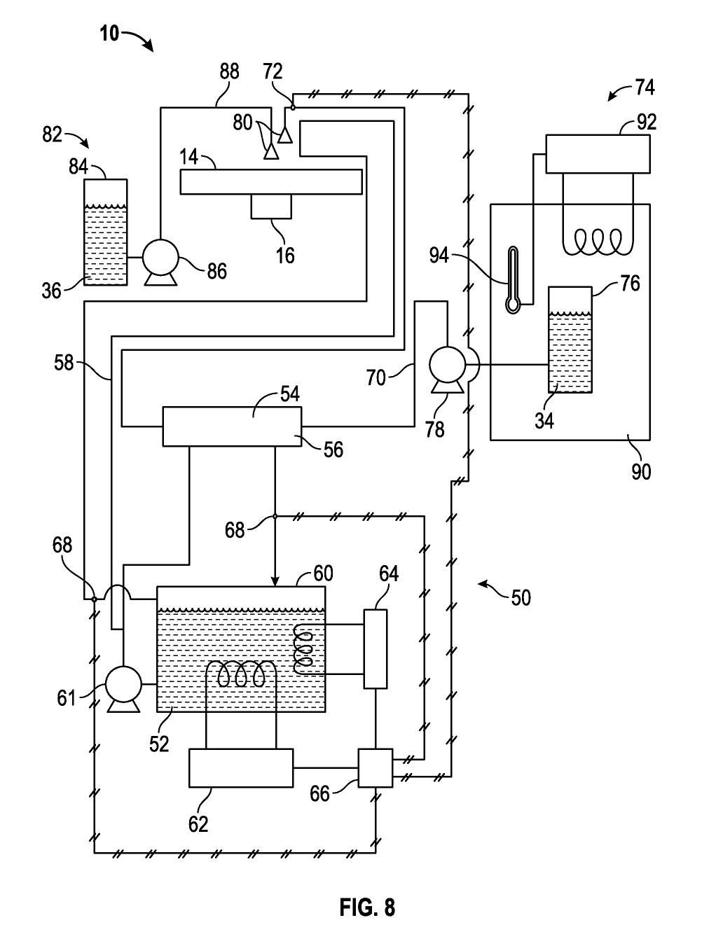

FIG. 8 illustrates one embodiment of a spin coating system 10 with a heat transfer system 50 coupled to a RRC solvent dispensing system 74. The solvent storage tank 76 is positioned in a temperature controlled storage area 90, and the temperature in the temperature controlled storage area 90 is set at the desired solvent dispensing temperature. The temperature controlled storage area 90 maintains a desired temperature with a storage area heating and/or cooling element 92 coupled to a storage area temperature sensing element 94. The solvent line 70 enters a heat exchanger 56, which is part of the heat transfer system 50, to adjust the temperature. The heat transfer control unit 66 is coupled to two different heat transfer temperature sensing elements 68 and a solvent temperature sensing element 72. A heat transfer pump 61 moves heat transfer fluid 52 through the heat exchanger 56, and a coating fluid dispensing system 82 dispenses coating fluid 36 on the wafer.

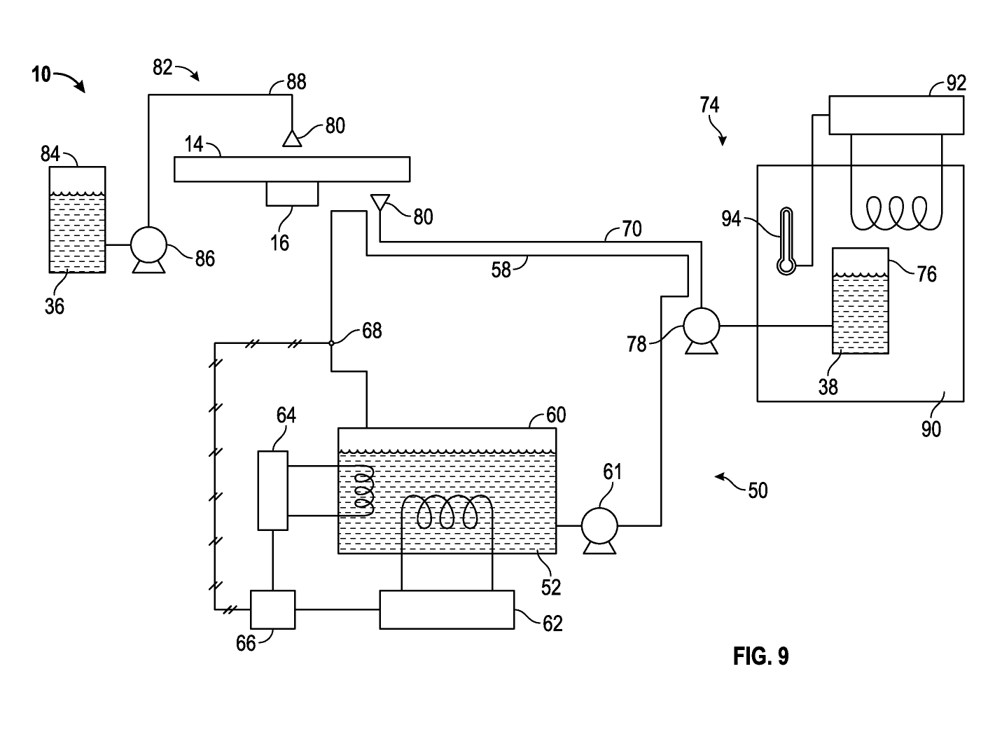

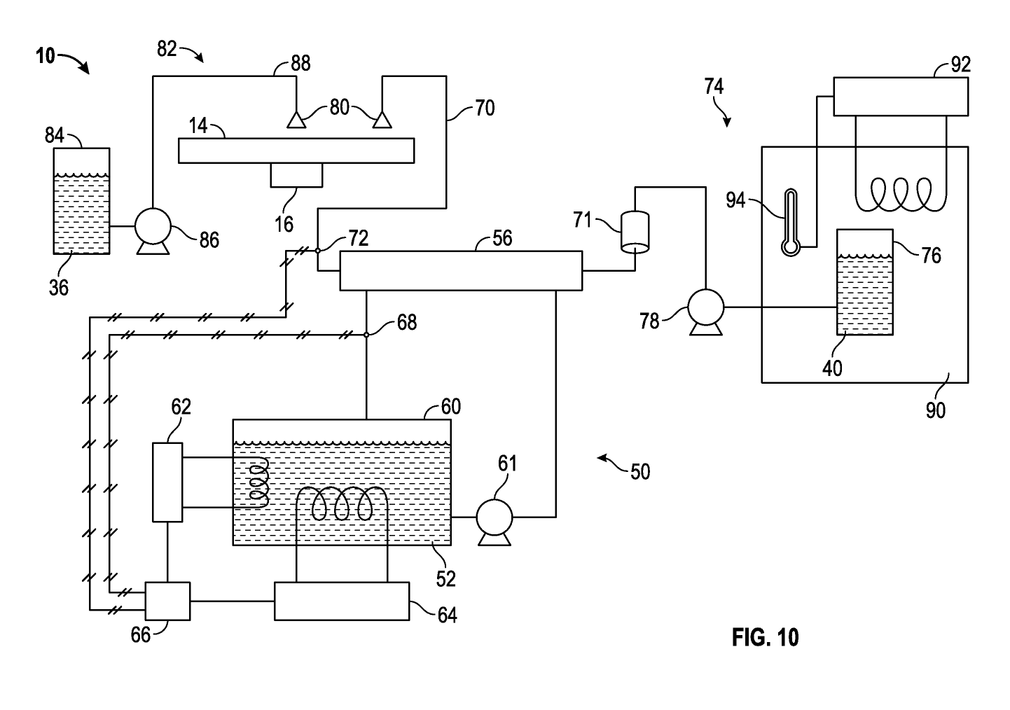

FIG. 9 illustrates another embodiment of a spin coating system 10 with a tracing line 58 and a BSR solvent dispensing system 74. The solvent storage tank 76 is positioned within the temperature controlled storage area 90, and the heat transfer control unit 66 is coupled to one heat transfer temperature sensing element 68. FIG. 10 illustrates yet another embodiment of a spin coating system 10 with a heat exchanger 56 and a solvent dispensing system 74 for EBR solvent 40. The duty on the heat exchanger 56 can be reduced or eliminated by using a temperature controlled storage area 90. In yet other embodiments, the temperature of the solvent is controlled with just the temperature controlled storage area 90 and insulation 71 on the solvent line 70.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

What is claimed is:

1. A spin coating system for coating a wafer comprising:
a chuck with an attachment point for attaching the wafer, where the chuck is rotatable;
a solvent dispensing system configured for depositing solvent on the wafer;
a solvent temperature sensing element coupled to the solvent dispensing system; and
a heat transfer system coupled to the solvent temperature sensing element and to the solvent dispensing system, wherein the heat transfer system is configured to adjust a solvent temperature in the solvent dispensing system.

2. The spin coating system of claim 1 wherein the wafer comprises a coating side, and wherein the solvent dispensing system is configured to dispense a reduced resist consumption solvent on the coating side within 1 centimeter of a wafer center point.

3. The spin coating system of claim 2 further comprising a coating fluid dispensing system, and wherein the solvent dispensing system and the coating fluid dispensing system are positioned to dispense material on the coating side.

4. The spin coating system of claim 1 wherein the wafer comprises a back side, and wherein the solvent dispensing system is configured to dispense a back side rinse solvent on the back side.

5. The spin coating system of claim 1 wherein the wafer comprises a coating side, and wherein the solvent dispensing system is configured to dispense an edge bead removal solvent on the coating side within about 5 millimeters of a wafer outer edge.

6. The spin coating system of claim 1 wherein the heat transfer system further comprises a heat transfer device, and the heat transfer system is coupled to the solvent dispensing system through the heat transfer device.

7. The spin coating system of claim 6 wherein the heat transfer system further comprises a heat transfer control unit coupled to the solvent temperature sensing element, and wherein the heat transfer control unit is configured to adjust a heat transfer fluid temperature based on readings from the solvent temperature sensing element.

8. The spin coating system of clam 1 further comprising a temperature controlled storage area, and wherein the solvent dispensing system further comprises a solvent storage tank positioned within the temperature controlled storage area.

9. A spin coating system for coating a wafer comprising:
a chuck with an attachment point for the wafer, where the chuck is rotatable;
a solvent dispensing system comprising a nozzle, wherein the nozzle is positioned to dispense on the wafer;
a heat transfer system comprising a heat transfer device, and wherein the heat transfer system is coupled to the solvent dispensing system through the heat transfer device; and
a heat transfer temperature sensing element positioned in the heat transfer system, wherein the heat transfer system is configured to adjust a heat transfer fluid temperature in response to readings from the heat transfer temperature sensing element.

10. The spin coating system of claim 9 where the heat transfer device comprises a tracing line, the solvent dispensing system comprises a solvent line, and the tracing line is positioned adjacent to the solvent line.

11. The spin coating system of claim 9 where the heat transfer device comprises a heat exchanger, and wherein the heat exchanger is coupled to the solvent dispensing system.

12. The spin coating system of claim 9 further comprising a temperature controlled storage area, and wherein the solvent dispensing system further comprises a solvent storage tank positioned within the temperature controlled storage area.

13. The spin coating system of claim 9 wherein the wafer comprises a coating side, and wherein the nozzle is positioned to dispense a reduced resist consumption solvent on the coating side.

14. The spin coating system of claim 13 further comprising a coating fluid dispensing system, and wherein the nozzle and the coating fluid dispensing system are positioned to dispense on the coating side.

15. The spin coating system of claim 9 wherein the wafer comprises a back side, and wherein the nozzle is positioned to dispense a back side rinse solvent on the back side.

16. The spin coating system of claim 9 wherein the wafer comprises a coating side, and wherein the nozzle is positioned to dispense an edge bead removal solvent on the coating side within about 5 millimeters of a wafer outer edge.

17. A method for spin coating a wafer, the method comprising:
attaching the wafer to a chuck, wherein the chuck is rotatable;
rotating the wafer on the chuck; and
dispensing a solvent onto the wafer while controlling a solvent dispensing temperature.

18. The method of claim 17 wherein dispensing the solvent onto the wafer while controlling the solvent dispensing temperature further comprises controlling the solvent dispensing temperature to within a solvent dispensing temperature range with a heat transfer system.

19. The method of claim 18 wherein controlling the solvent dispensing temperature with a heat transfer system further comprises controlling the solvent dispensing temperature with a heat transfer system comprising a heat transfer control unit coupled to a solvent temperature sensing element.

20. The method of claim 17 wherein dispensing the solvent further comprises dispensing solvent comprising a reduced resist consumption solvent, a back side rinse solvent, or an edge bead removal solvent.
